(19) United States
(12) Patent Application Publication
(10) Pub. No.: US 2016/0206085 A1
(43) Pub. Date: Jul. 21, 2016

(54) Single-Handed Operation Assisting Device for Handheld Device

(71) Applicant: CHENG-CHIEH LIN, Tainan City (TW)

(72) Inventor: CHENG-CHIEH LIN, Tainan City (TW)

(21) Appl. No.: 14/598,294

(22) Filed: Jan. 16, 2015

(51) Int. Cl. A45F 5/10; H05K 5/02; G06F 3/041

(52) U.S. Cl. CPC A45F 5/10; G06F 3/0412; H05K 5/023

(57) ABSTRACT

A single-handed operation assisting device for a handheld device includes a fixing part for securing a handheld device by clamping, suction, adhesion, or enclosing. In addition, an integrally formed, foldable, or detachable finger straddle part is provided at one side of the fixing part to be straddled between any two fingers, excluding the thumb, of one of the user's hands while the four fingers of the same hand extend downward to support the back of the handheld device so that the handheld device can be held firmly and single-handedly without slipping. As the handheld device is supported at a position adjacent to one of its edges, the user's thumb can reach a farther portion or the lower inner end of the screen with respect to where the handheld device is held, thereby achieving ease of full-screen touch control.

### BACKGROUND OF THE INVENTION

1. Technical Field

The present invention relates to an assisting device which can secure a handheld device (e.g., one with a large screen) and be held single-handedly so that the user can perform full-screen operation with the thumb of the holding hand moving between the far-end side and near-end side of the screen while supporting the handheld device with the four fingers of the holding hand placed near one edge of the handheld device, thereby achieving the object of holding and operating the handheld device with one hand.

2. Description of Related Art

When an electronic handheld device such as a mobile phone is used other than, for example, to watch movies, listen to music, read texts, or simply as a telephone, the application programs of the mobile phone typically require the mobile phone to be operated and controlled with fingers, wherein the modes of operation and control include searching, inputting, clicking, setting, executing, and the like. In addition, it seems generally desirable that a mobile phone can be easily operated with only one hand, whether it is due to personal habits or when the other hand is holding another article, grasping a support in a vehicle during a ride, or using an eating utensil. Therefore, theoretically, an electronic handheld device with a 3.5-inch screen should be able to provide the most comfortable single-handed operation experience to most people. However, consumers tend to favor electronic handheld devices with larger screens because of their better visual effects. Such large-screen electronic handheld devices are nevertheless difficult to hold in one hand and operate at the same time through full-screen touch control by the thumb of the holding hand. In particular, the thumb is very likely to have problem reaching the upper outer end or lower inner end of the screen with respect to where the handheld device is held.

Certain mobile phones on the market, especially those with a large screen, use different methods to improve the operation interface of the screen. For instance, iPhone 6 is so designed that, by tapping the Home button twice, the content displayed at the upper end of the screen is moved downward to facilitate single-handed operation. As another example, a user of Samsung Galaxy Note 3/4 can slide the midpoint of either the left or right edge of the screen toward the screen center to reduce the screen image while moving the reduced image to a specific position to facilitate single-handed operation, or to move the touch control icons on the screen to an area reachable by the thumb.

However, not all large-screen electronic handheld devices or APPs (application software) have the foregoing designs, and reducing the screen image departs from the original design principle of large-screen display. Some people may think it is all right to operate an electronic handheld device with both hands, but the importance of a single-handed operation design will be known when such operation is actually required. After all, it is more efficient and convenient if one can hold and operate an electronic handheld device with one hand and leave the other hand free to do other things as well.

### BRIEF SUMMARY OF THE INVENTION

In order to overcome the difficulty of holding and operating a large-screen electronic handheld device by touch control with the same hand, the present invention provides an assisting device having a fixing part and a finger straddle part. The fixing part is capable of clamping the majority of large-screen handheld devices of different screen sizes. The finger straddle part extends from the handheld end of the fixing part and can be straddled by the juncture of any two adjacent ones of the four fingers (excluding the thumb) of a user's hand while the back of the handheld device is supported by the four fingers extending downward to jointly provide stable three-point support, allowing the handheld device to be held with only one hand. In the meantime, the thumb of the same hand can extend farther over the screen or to a position near the handheld portion for full-screen touch control. Thus, the user can hold and operate the handheld device single-handedly with greater ease.

The technical scheme adopted by the present invention to solve the foregoing technical problems involves a fixing part on which a handheld device with a touch screen can be fixedly arranged and a finger straddle part which is provided at and extends outward from one side of the fixing part, has a straddle surface, and can be straddled between two fingers of a user's hand holding the handheld device.

In the technical scheme, the straddle surface of the finger straddle part is higher than the touch screen when the handheld device is fixedly arranged on the fixing part.

In the technical scheme, the finger straddle part has a generally elongated shape.

In the technical scheme, the fixing part includes a fixed clamping end element and a movable clamping end element. The fixed clamping end element has a fixed clamping edge. The movable clamping end element is inserted in one end of the fixed clamping end element and has a movable clamping edge opposite the fixed clamping edge. The movable clamping end element is elastically biased toward the fixed clamping end element. The finger straddle part is provided at an outer side of the fixed clamping end element.

In the technical scheme, a recess is provided at the bottom of the finger straddle part and has a middle portion provided with a downwardly extending shaft, a stepped hole which has a step and in which the shaft is inserted is formed V a large hole and a small hole at a corresponding position of the fixed clamping end element, a spring is arranged in the stepped hole and has one end seated on the step, and a threaded fastener is fastened to the distal end of the shaft and pressed against the other end of the spring, allowing the finger straddle part to be pulled upward and turned and the recess of the finger straddle part to reengage with the fixed clamping end element after the finger straddle part is released.

In the technical scheme, the finger straddle part and the fixed clamping end element have end surfaces which can be connected with each other and which are respectively embedded with strong magnetic elements. In addition, the two end surfaces are respectively provided with a sunken engaging portion and a protruding engaging portion which can engage with each other to prevent rotation.

Thus, after the handheld device is secured by the fixing part of the invention by clamping, suction, adhesion, or enclosing, the user can put any two of the four fingers (excluding the thumb) of one hand astride the finger straddle part and support the back of the handheld device with the four fingers such that the handheld device is stably held with three-point support. The user can further change the position of the palm of the holding hand to enable the thumb to carry out such touch control operations as clicking at or performing a dragging action on any part of a large screen so that the object of holding and operating the handheld device single-handedly is achieved.

### BRIEF DESCRIPTION OF THE SEVERAL VIEWS OF THE DRAWINGS

FIG. 1 is a perspective view of the present invention;

FIG. 2 is an exploded perspective view of the structure of the present invention;

FIG. 3 is a side sectional view of the structure of the present invention;

FIG. 4 shows how the present invention is folded;

FIG. 5 shows how the present invention is held and operated;

FIG. 6 shows another embodiment of the storable structure of the finger straddle part; and

FIG. 7 shows an attachment feature of the present invention.

### DETAILED DESCRIPTION OF THE INVENTION

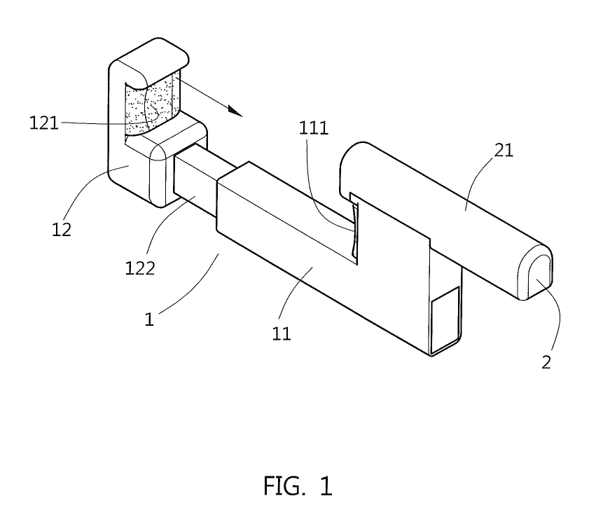

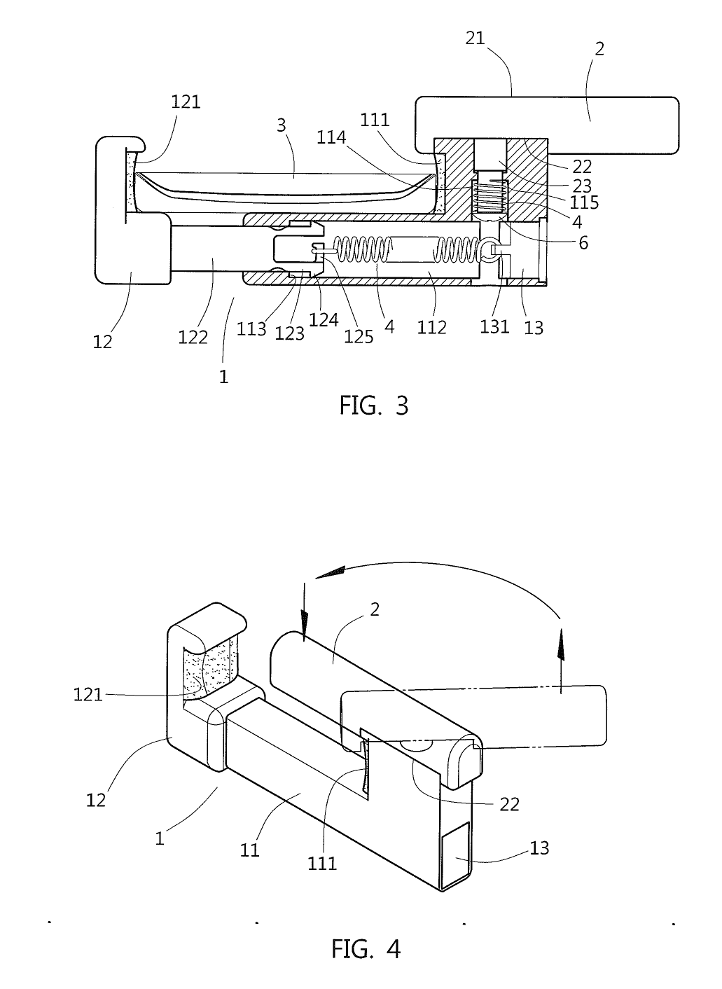

Referring to FIG. 1, the present invention provides an assisting device with which a handheld device with a touch screen can be held with one hand and operated via touch control by the thumb of the same hand. The assisting device essentially includes a fixing part 1 for fixing a handheld device and a finger straddle part 2 extending outward from one side of the fixing part 1. The finger straddle part 2 is of a generally elongated shape and has a top end forming a straddle surface 21. The straddle surface 21, as shown in FIG. 3, is higher than the touch screen of the handheld device 3.

The fixing part 1 can be provided with a suction disc for holding a handheld device by suction, or an adhesive part for securing a handheld device adhesively, or a back cover for use with a handheld device, or a clamping device for clamping a handheld device. The aforesaid suction disc, adhesive part, and back cover are conventional means for securing a handheld device and therefore are not shown in the drawings. Herein, only a clamping device is described by way of example.

The clamping device includes a fixed clamping end element 11 and a movable clamping end element 12 telescopically inserted in one end of the fixed clamping end element 11. The finger straddle part 2 is arranged on and extends outward from the fixed clamping end element 11. The corresponding portions of the upper inner sides of the fixed clamping end element 11 and the movable clamping end element 12 are respectively provided with a fixed clamping edge 111 and a movable clamping edge 121 opposite the fixed clamping edge 111 so that two opposite sides of a handheld device can be clamped and fixed between the fixed clamping edge 111 and the movable clamping edge 121. The finger straddle part 2 extends outward from the fixed clamping edge 111. The movable clamping end element 12 is biased toward the fixed clamping end element 11 by an elastic pulling force.

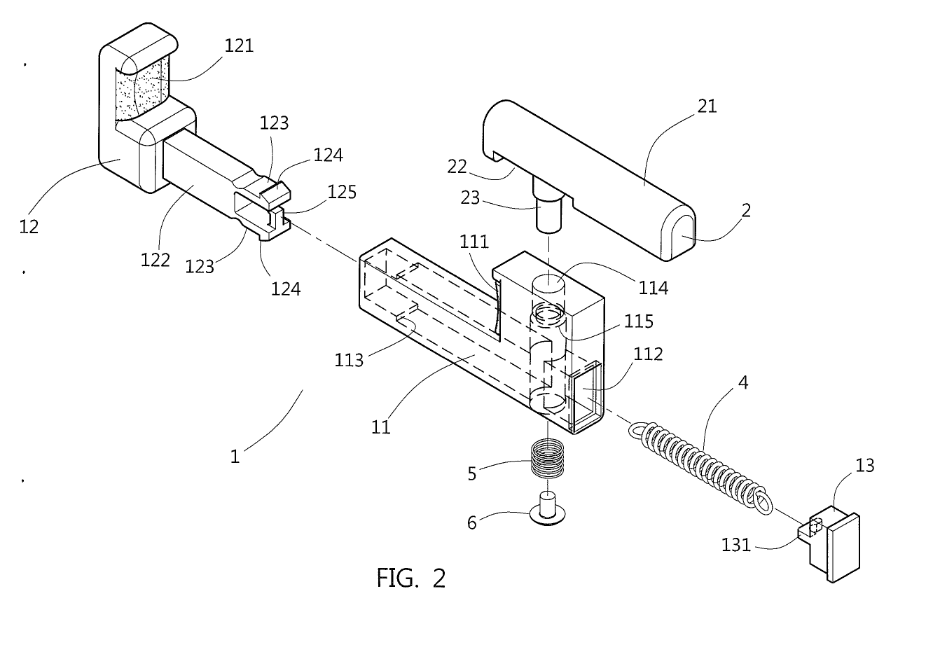

Referring to FIG. 2 and FIG. 3, the movable clamping end element 12 is provided with a penetrating end 122 in addition to the movable clamping edge 121. The penetrating end 122 extends into a stepped hole 112 formed by a large hole and a small hole at a corresponding position of the fixed clamping end element 11. The distal end of the penetrating end 122 is formed with two elastic legs 123, and the outer edges of the distal ends of the two elastic legs 123 are formed with opposite engaging portions 124 respectively. Moreover, a hooking part 125 is provided at a predetermined position on the penetrating end 122, and a side cover 13 is provided at and covers the other end of the stepped hole 112. The inner end of the side cover 13 is also provided with a hooking part 131. A spring 4 is hooked to and arranged between the two hooking parts 125 and 131 so that the movable clamping end element 12 not only can move in a telescoping manner along the stepped hole 112, but also tends to move elastically inward by virtue of the spring 4 (i.e., being biased toward the fixed clamping end element 11 by an elastic force, as stated above). When the movable clamping end element 12 is pulled outward to the greatest extent, the engaging portions 124 at the distal ends of the two elastic legs 123 are engaged with a step 113 in the stepped hole 112 such that the movable clamping end element 12 is stopped and is kept from separating from the fixed clamping end element 11.

The finger straddle part 2 has a generally elongated shape and is formed with a recess 22 at a position where the finger straddle part 2 is connected with the fixed clamping end element 11. A shaft 23 extends downward from the middle of the recess 22 and is inserted in a stepped hole 114 formed by a large hole and a small hole at a corresponding position of the fixed clamping end element 11, wherein the stepped hole 114 has a step 115. In addition, a spring 5 is arranged in the stepped hole 114 and seated on the step 115, and a threaded fastener 6 is fastened to the distal end of the shaft 22 such that the two ends of the spring 5 are pressed against the step 115 and the threaded fastener 6 respectively. As a result, the finger straddle part 2 is biased toward the fixed clamping end element 11 by an elastic force, and the recess 22 of the finger straddle part 2 is engaged with a corresponding portion of the fixed clamping end element 11 and is prevented from arbitrary rotation.

Referring to FIG. 4, when the single-handed operation assisting device of the present invention is not in use, the finger straddle part 2 can be pulled upward so that the recess 22 of the finger straddle part 2 is disengaged from the fixed clamping end element 11. Then, the finger straddle part 2 is rotated to turn its outwardly extending portion inward. Once the finger straddle part 2 is released, it is pulled downward by the elastic force of the spring 5 such that the recess 22 is engaged with the fixed clamping end element 11 again. Thus, the single-handed operation assisting device is reduced in size and can be carried around or stored conveniently.

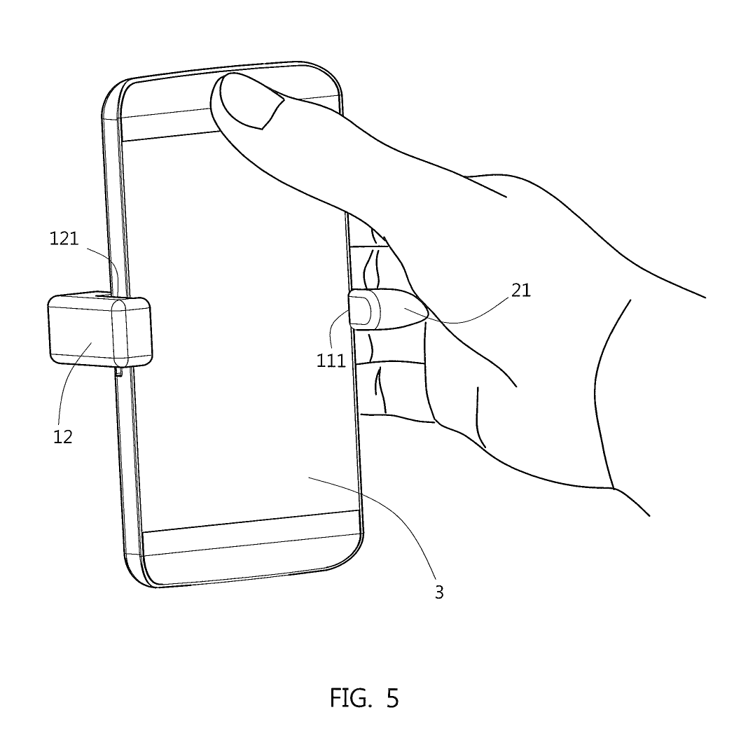

A mode of use of the single-handed operation assisting device is described below with reference to FIG. 5. To begin with, the handheld device 3 is clamped between the fixed and movable clamping edges 111, 121 of the fixed and movable clamping end elements 11, 12 of the fixing part 1. After that, the user puts any two of the four fingers (excluding the thumb) of one hand astride the straddle surface 21 of the finger straddle part 2 and stretches the four fingers downward to prop the back of the handheld device 3. Thus, thanks to the single-handed operation assisting device of the present invention, the handheld device 3 is supported by at least three points (namely the straddle portion between the straddling fingers and the tips of the fingers in contact with the back of the handheld device 3) and is stably held in one hand. The handheld device 3, therefore, not only is prevented from slipping off the hand, but also is held at a position adjacent to one of its edges so that, by changing the position of the palm, the user can reach the thumb to screen portions farther from or closer to the held portion for full-screen touch control. Even if the handheld device has a relatively large screen, it can be held with one hand and easily operated by touching whichever part of the screen with the thumb of the same hand.

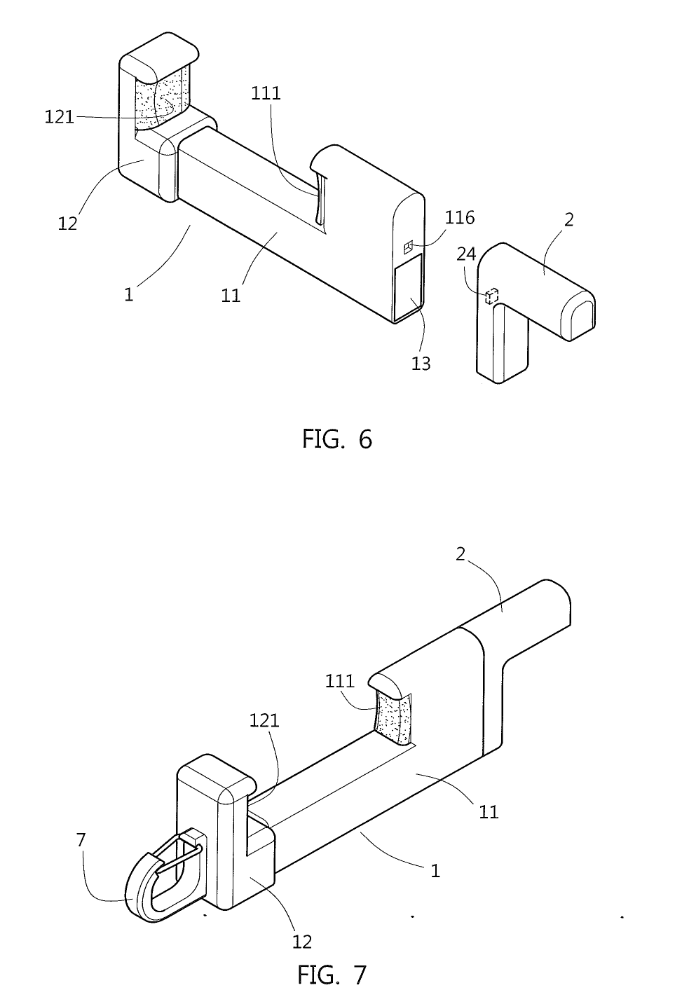

The finger straddle part 2 can be alternatively designed as shown in FIG. 6, in which the fixed clamping end element 11 and the finger straddle part 2 are respectively formed with corresponding connectable end surfaces and the two opposite end surfaces are respectively provided with a sunken engaging portion 116 and a protruding engaging portion 24 which correspond to each other and are engageable to prevent rotation. In addition, the two opposite connectable end surfaces are respectively embedded with strong magnetic elements (not shown) which can be magnetically attached to each other, allowing the finger straddle part 2 and the fixed clamping end element 11 to be connected for use or separated for easy carry and storage.

Referring to FIG. 7, one end of the single-handed operation assisting device of the present invention is provided with a snap hook 7 so that the single-handed operation assisting device can be hooked to the waist of the user's clothes or to a handbag, a knapsack, or the like.

What is claimed is:

1. A single-handed operation assisting device for a handheld device, comprising: a fixing part on which a handheld device with a touch screen can be fixedly arranged; and a finger straddle part formed at and extending outward from a lateral side of the fixing part and having a straddle surface so as to be straddled between two fingers of a user's hand holding the handheld device.

2. The single-handed operation assisting device of claim 1, wherein the straddle surface of the finger straddle part is higher than the touch screen when the handheld device is fixedly arranged on the fixing part.

3. The single-handed operation assisting device of claim 1, wherein the finger straddle part is of a generally elongated shape.

4. The single-handed operation assisting device of claim 1, wherein the fixing part comprises a fixed clamping end element and a movable clamping end element, the fixed clamping end element has a fixed clamping edge, the movable clamping end element is inserted in one end of the fixed clamping end element and has a movable clamping edge opposite the fixed clamping edge, the movable clamping end element is elastically biased toward the fixed clamping end element, and the finger straddle part is provided at an outer side of the fixed clamping end element.

5. The single-handed operation assisting device of claim 1, wherein the finger straddle part has a bottom provided with a recess, the recess has a middle portion provided with a downwardly extending shaft, the fixing part has a portion corresponding to the shaft and provided with a stepped hole formed by a large hole and a small hole, the stepped hole has a step, the shaft is inserted in the stepped hole, the stepped hole receives a spring therein, the spring has one end seated on the step, and the shaft has a distal end fastened with a threaded fastener pressed against an opposite end of the spring such that not only can the finger straddle part be pulled upward and turned, but also the recess of the finger straddle part is reengaged with the fixing part once the finger straddle part is released.

6. The single-handed operation assisting device of claim 1, wherein the finger straddle part and the fixing part have end surfaces which are connectable with each other, respectively embedded with strong magnetic elements, and respectively provided with a sunken engaging portion and a protruding engaging portion engageable with the sunken engaging portion to prevent rotation.
